(19) United States
(12) Patent Application Publication
(10) Pub. No.: US 2024/0030083 A1
(43) Pub. Date: Jan. 25, 2024

(54) SEMICONDUCTOR PACKAGE AND METHOD OF MANUFACTURING THE SEMICONDUCTOR PACKAGE

(71) Applicant: SAMSUNG ELECTRONICS CO., LTD., Suwon-si (KR)

(72) Inventors: Yikoan HONG, Suwon-si (KR); Seokho KIM, Suwon-si (KR); Kwangjin MOON, Suwon-si (KR)

(21) Appl. No.: 18/187,444

(22) Filed: Mar. 21, 2023

(30) Foreign Application Priority Data
Jul. 25, 2022 (KR) 10-2022-0091908

(51) Int. Cl. H01L 23/34; H01L 25/065; H01L 23/00

(52) U.S. Cl. CPC H01L 23/34; H01L 25/0657; H01L 24/08; H01L 2224/08146; H01L 2224/08221; H01L 2924/182

(57) ABSTRACT

A semiconductor package includes a semiconductor substrate and a semiconductor chip in contact with the semiconductor substrate. The semiconductor chip has a first surface facing the semiconductor substrate and an opposite second surface. The semiconductor chip has a die region, an edge region extending around the die region and a plurality of air exhaust passages extending from the die region to an outer surface of the edge region in the first surface of the semiconductor chip. Each of the air exhaust passages includes an inlet having a first passage area, and an outlet having a second passage area greater than the first passage area.

### PRIORITY STATEMENT

This application claims priority under 35 U.S.C. § 119 to Korean Patent Application No. 10-2022-0091908, filed on Jul. 25, 2022 in the Korean Intellectual Property Office (KIPO), the contents of which are herein incorporated by reference in its entirety.

### BACKGROUND

### 1. Field

Example embodiments relate to semiconductor packages and methods of manufacturing semiconductor packages. More particularly, example embodiments relate to a semiconductor package including a plurality of semiconductor chips disposed on a semiconductor substrate and a method of manufacturing the semiconductor package.

### 2. Description of the Related Art

In a bonding process for mounting a semiconductor chip on a semiconductor substrate, air introduced and trapped between the semiconductor substrate and the semiconductor chip may generate voids. When such voids remain between the semiconductor substrate and the semiconductor chip, there may be a problem in that an adhesive force between the semiconductor substrate and the semiconductor chip may be weakened and productivity may be reduced.

### SUMMARY

Example embodiments provide semiconductor packages including air exhaust passages for removing trapped air or gas from semiconductor chips.

Example embodiments provide methods of manufacturing semiconductor packages.

According to example embodiments, a semiconductor package includes a semiconductor substrate and at least one semiconductor chip in contact with the semiconductor substrate. The at least one semiconductor chip has a first surface facing the semiconductor substrate and an opposite second surface. The at least one semiconductor chip has a die region, an edge region extending around the die region and a plurality of air exhaust passages extending from the die region to an outer surface of the edge region in the first surface of the at least one semiconductor chip. Each of the air exhaust passages includes an inlet having a first passage area, and an out let having a second passage area greater than the first passage area.

According to example embodiments, a semiconductor package includes a semiconductor substrate and at least one semiconductor chip on the semiconductor substrate. The at least one semiconductor chip has a first surface in contact with the semiconductor substrate and an opposite second surface. The at least one semiconductor chip includes a die region, an edge region extending around the die region, and a plurality of air exhaust passages extending from the die region to an outer surface of the edge region. Each air exhaust passage has an inlet having a first passage area and an outlet having a second passage area greater than the first passage area.

According to example embodiments, a semiconductor package includes a first semiconductor substrate and a second semiconductor substrate on the first semiconductor substrate. The second semiconductor substrate includes a chip region, an outermost edge region extending around the chip region, and a plurality of air exhaust passages recessed from a first surface that faces the first semiconductor substrate and extending from the chip region to an outer surface of the outermost edge region. Each of the air exhaust passages includes an inlet having a first passage area through, and an outlet having a second passage area greater than the first passage area.

According to example embodiments, a semiconductor package may include a semiconductor substrate and at least one semiconductor chip in contact with the semiconductor substrate. The at least one semiconductor chip may have a first surface facing the semiconductor substrate and an opposite second surface. The at least one semiconductor chip may have a die region, an edge region extending around the die region and a plurality of air exhaust passages extending from the die region to an outer surface of the edge region in the first surface of the at least one semiconductor chip. Each of the air exhaust passages may include an inlet having a first passage area, and an outlet having a second passage area greater than the first passage area.

Thus, the air trapped between the semiconductor substrate and the at least one semiconductor chip may be exhausted to an outside of the semiconductor package through the air exhaust passages. The first passage area of the inlet and the second passage area of the outlet may generate a pressure difference in the air exhaust passages. The air trapped inside the semiconductor package may be exhausted to the outside along the air exhaust passage by the pressure difference. Since the air is exhausted to the outside of the semiconductor package, adhesion between the semiconductor substrate and the at least one semiconductor chip may be enhanced.

### BRIEF DESCRIPTION OF THE DRAWINGS

Example embodiments will be more clearly understood from the following detailed description taken in conjunction with the accompanying drawings. FIGS. 1 to 22 represent non-limiting, example embodiments as described herein.

FIG. 1 is a cross-sectional view illustrating a semiconductor package in accordance with example embodiments.

FIG. 2 is an enlarged perspective view illustrating a portion ‘A’ in FIG. 1.

FIGS. 3 to 19 are views illustrating a method of manufacturing a semiconductor package in accordance with example embodiments.

FIG. 20 is a cross-sectional view illustrating a semiconductor package including a plurality of semiconductor substrates in accordance with example embodiments.

FIG. 21 is an enlarged plan view illustrating a portion ‘F’ in FIG. 20.

FIG. 22 is an enlarged perspective view illustrating a portion ‘F’ in FIG. 20.

### DETAILED DESCRIPTION OF EXAMPLE EMBODIMENTS

Hereinafter, example embodiments will be explained in detail with reference to the accompanying drawings.

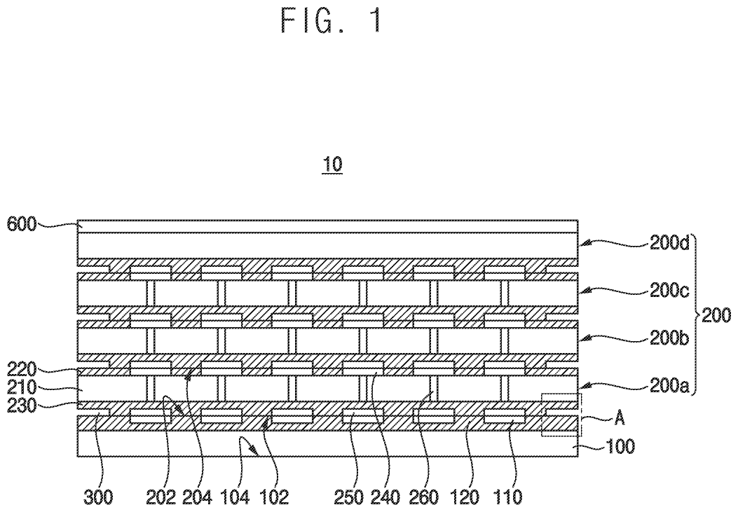

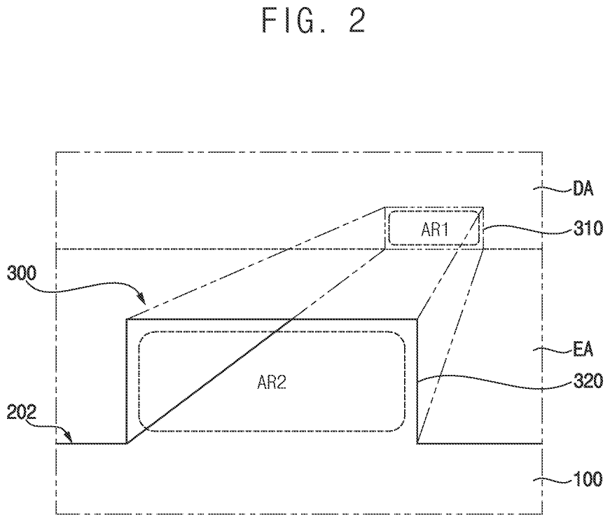

FIG. 1 is a cross-sectional view illustrating a semiconductor package in accordance with example embodiments. FIG. 2 is an enlarged perspective view illustrating a portion ‘A’ in FIG. 1.

Referring to FIGS. 1 and 2, the semiconductor package 10 may include a buffer die 100 and a plurality of semiconductor chips stacked on the buffer die 100. The semiconductor package 10 may include first to fourth semiconductor chips 200a, 200b, 200c, 200d stacked on the buffer die 100.

The plurality of semiconductor chips 200a, 200b, 200c, 200d may be vertically stacked on the buffer die 100. In this embodiment, the buffer die 100 and the first to fourth semiconductor chips 200a, 200b, 200c, 200d may be substantially the same as or similar to each other. Thus, same or similar components may be denoted by the same or similar reference numerals, and repeated descriptions of the same components will be omitted.

The buffer die 100 may be a chip having an upper surface 102 and a lower surface 104 facing each other. The buffer die 100 may include a substrate pad 110 and a substrate insulating layer 120 exposing the substrate pad 110. The substrate pad 110 may be provided on the upper surface 102 of the buffer die 100.

In this embodiment, it is exemplified that the semiconductor package as a multi-chip package includes the buffer die 100 and four stacked semiconductor chips 200a, 200b, 200c, 200d. However, the present invention is not limited thereto, and for example, the semiconductor package may include 8, 12, or 16 stacked semiconductor chips.

Each of the first to fourth semiconductor chips 200a, 200b, 200c, 200d may include an integrated circuit chip that is completed by performing semiconductor manufacturing processes. For example, each of the semiconductor chips may include a memory chip or a logic chip. The semiconductor package 10 may include a memory device. The memory device may include a high bandwidth memory (HBM) device.

The semiconductor chip 200 may be disposed in contact with the buffer die 100. The semiconductor chip 200 may include a first surface 202 and a second surface 204 opposite to each other. The first surface 202 of the semiconductor chip 200 may face the buffer die 100 and may be disposed on the buffer die 100.

The first surface 202 of the semiconductor chip 200 may be disposed to face the upper surface 102 of the buffer die 100. A lower insulating layer 230 of the semiconductor chip 200 and the buffer die 100 may be directly bonded to each other. Accordingly, a second bonding pad 250 and the substrate pad 110 may be bonded to each other between the buffer die 100 and the semiconductor chip 200 by Cu-Cu hybrid bonding. For example, pad-to-pad direct bonding may be formed.

In example embodiments, the semiconductor chip 200 may include a silicon substrate 210, an upper insulating layer 220 having a first bonding pad 240 on an outer surface thereof, and the lower insulating layer 230 having the second bonding pad 250. Also, the semiconductor chip 200 may include a through electrode 260 penetrating the silicon substrate 210.

The silicon substrate 210 may have an active surface and an inactive surface opposite to each other. Circuit patterns may be provided on the active surface of the silicon substrate 210. For example, the silicon substrate 210 may include a semiconductor material such as silicon, germanium, or silicon-germanium. The silicon substrate 210 may include a III-V compound semiconductor such as gallium phosphide (GaP), gallium arsenide (GaAs), gallium antimonide (GaSb), or the like.

The circuit patterns may include transistors, diodes, and the like. The circuit patterns may constitute circuit elements. Accordingly, the semiconductor chip 200 may include a plurality of the circuit elements therein. The circuit pattern may include a transistor, a diode, or the like. The circuit pattern may be formed through a wafer process called a front-end-of-line (FEOL) process.

A wiring layer may be provided on one surface of the silicon substrate. The wiring layer may be formed on the one surface of the silicon substrate by a wiring process called a back-end-of-line. The wiring layer may include wirings therein. For example, the wirings may include aluminum (Al), copper (Cu), tin (Sn), nickel (Ni), gold (Au), platinum (Pt), or an alloy thereof.

The upper insulating layer 220 may be provided on the second surface 204 of the semiconductor chip 200. The upper insulating layer 220 may be formed on a front surface of the silicon substrate 210 as an interlayer insulating layer. The upper insulating layer 220 may include a plurality of insulating layers and wirings in the insulating layers. In addition, the first bonding pad 240 may be provided on the outermost insulating layer of the upper insulating layer 220.

The lower insulating layer 230 may be provided on the first surface 202 of the semiconductor chip 200. The lower insulating layer 230 may be formed on a rear surface of the silicon substrate 210 opposite to the front surface. The second bonding pad 250 may be provided on the lower insulating layer 230. The second bonding pad 250 may be disposed on an exposed surface of the through electrode 260. The lower insulating layer 230 may include silicon oxide, carbon-doped silicon oxide, silicon carbonitride (SiCN), or the like.

One end of the through electrode 260 may vertically penetrate the silicon substrate 210 to be electrically connected to the first bonding pad 240. The other end of the through electrode 260 may be electrically connected to the second bonding pad 250. Accordingly, the first and second bonding pads 240, 250 may be electrically connected to each other by the through electrode 260.

The first and second bonding pads 240, 250 and the through electrode 260 may include a same metal. For example, the metal may include copper (Cu). However, the present invention is not limited thereto, and may include a material (e.g., gold (Au)) that can be bonded by interdiffusion of metals by a high-temperature annealing process.

As illustrated in FIG. 2, in example embodiments, a plurality of air exhaust passages 300 may exhaust voids (i.e., trapped air or gas) generated between the semiconductor chip 200 and the buffer die 100 to an outside of the semiconductor package 10. The air exhaust passages 300 may exhaust the voids generated between different semiconductor chips to the outside of the semiconductor package 10. The air exhaust passages 300 may be provided on the first surface 202 on which the semiconductor chip 200 contacts the buffer die 100. The air exhaust passages 300 may be provided on one surface where different semiconductor chips 200 are in contact with each other.

The air exhaust passages 300 may extend from a die region DA to an outer surface of the edge region EA. The air exhaust passages 300 may be provided in the lower insulating layer 230 of the semiconductor chip 200. For example, the air exhaust passage 300 may have a trench shape in which the lower insulating layer 230 is recessed on the first surface 202 of the semiconductor chip 200.

The air exhaust passage 300 may include an inlet 310 through which air is introduced and an outlet 320 through which the air is exhausted. The air may be generated in a bonding process for bonding the buffer die 100 and the semiconductor chip 200. The air may be generated between the different semiconductor chips. The air may be generated between the buffer die 100 and the semiconductor chip 200.

The inlet 310 may be provided at a boundary between the die region DA and the edge region EA of the semiconductor chip 200. The inlet 310 may introduce the air generated between the buffer die 100 and the semiconductor chip 200 into the air exhaust passage 300. The inlet 310 may have a first passage area AR1.

The outlet 320 may be provided on the outer surface of the edge region EA of the semiconductor chip 200. The outlet 320 may be exposed toward the outer surface of the edge region EA. The outlet 320 may exhaust the air generated between the buffer die 100 and the semiconductor chip 200 from the air exhaust passage 300.

The outlet 320 may have a second passage area AR2. The second passage area AR2 of the outlet 320 may be greater than the first passage area AR1 of the inlet 310. Since the second passage area AR2 of the outlet 320 is greater than the first passage area AR1 of the inlet 310, a pressure in the outlet 320 may be lower than a pressure in the inlet 310. The air may move from the inlet 310 to the outlet 320 by a pressure difference between the outlet 320 and the inlet 310. For example, a ratio AR2/AR1 of the second passage area AR2 of the outlet 320 to the first passage area AR1 of the inlet 310 may be within a range of 1.1 to 3.

The air exhaust passage 300 may include a scribe lane region surrounding the die region. The scribe lane region may be a portion remaining after being removed by a sawing process among the scribe lane regions at the wafer level.

In example embodiments, a molding member 600 may be formed of an underfill resin such as an epoxy resin, and may include a silica filler or a flux. The molding member 600 may be formed of a polymer such as resin. For example, the molding member 600 may be formed of epoxy molding compound (EMC). The molding member 600 may be formed of a material different from or the same material as that of an underfill material layer.

As described above, the air generated between the different semiconductor chips 200 may be exhausted to the outside of the semiconductor package 10 through the air exhaust passage 300. The first passage area AR1 of the inlet 310 and the second passage area AR2 of the outlet 320 may generate the pressure difference inside the air exhaust passage 300. The air trapped inside the semiconductor package 10 may be exhausted to the outside along the air exhaust passage 300 by the pressure difference. Since the air is exhausted to the outside of the semiconductor package 10, adhesion between the buffer die 100 and the different semiconductor chips 200 may be enhanced.

Hereinafter, a method of manufacturing the semiconductor package of FIG. 1 will be described.

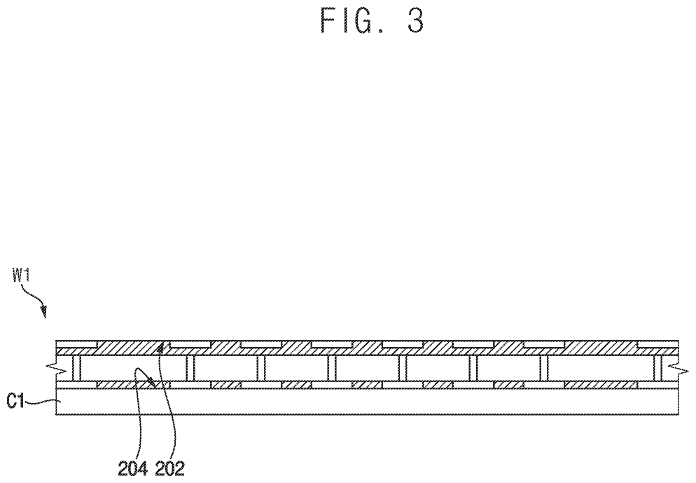

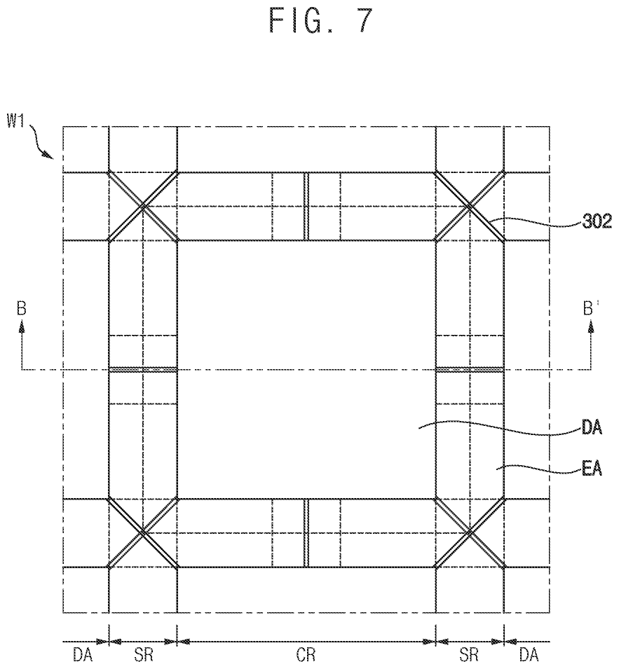

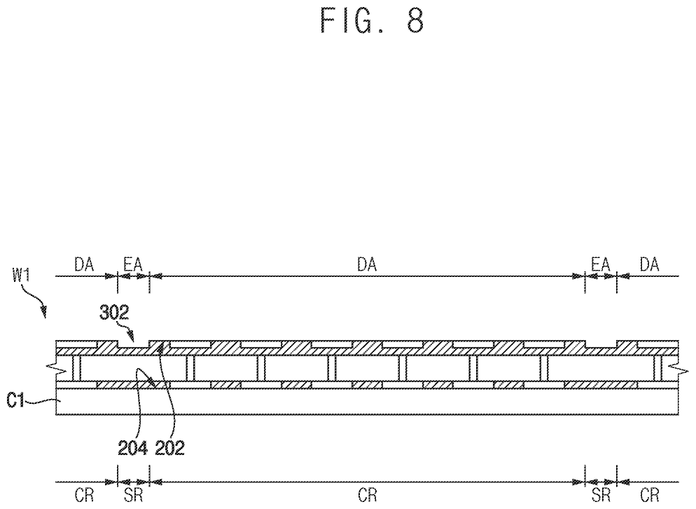

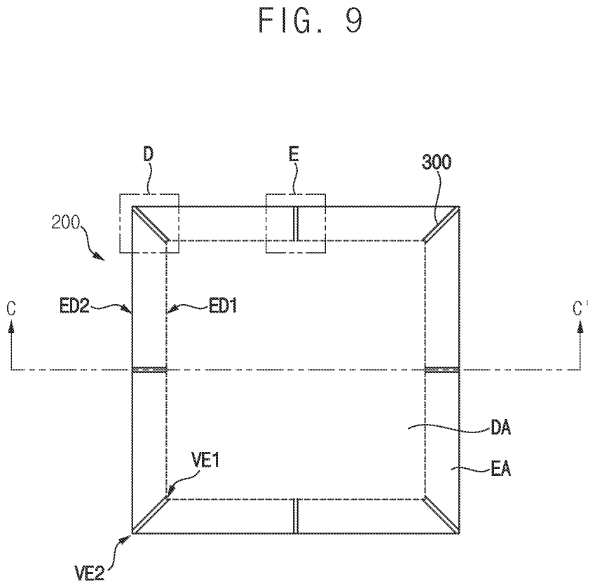

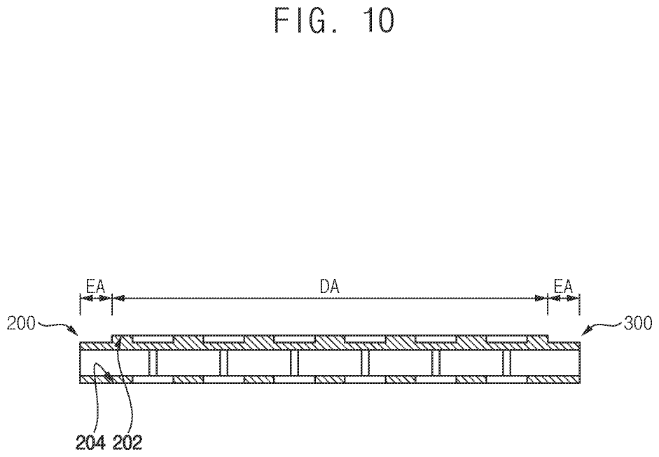

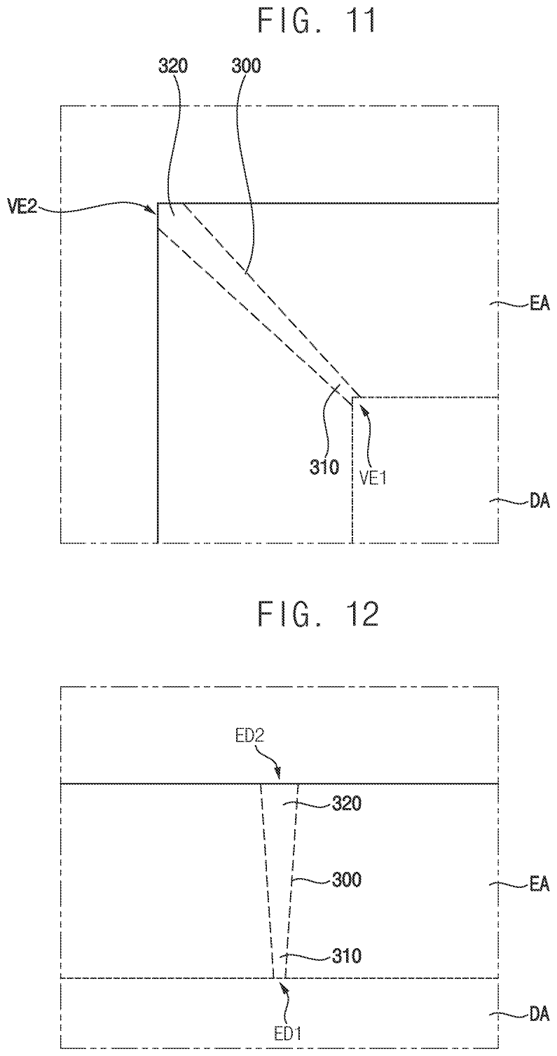

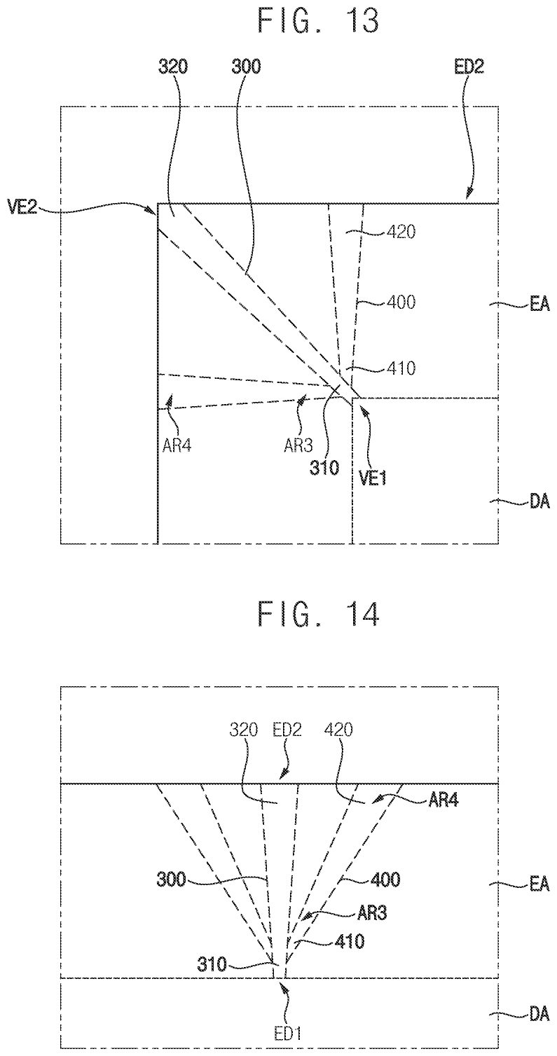

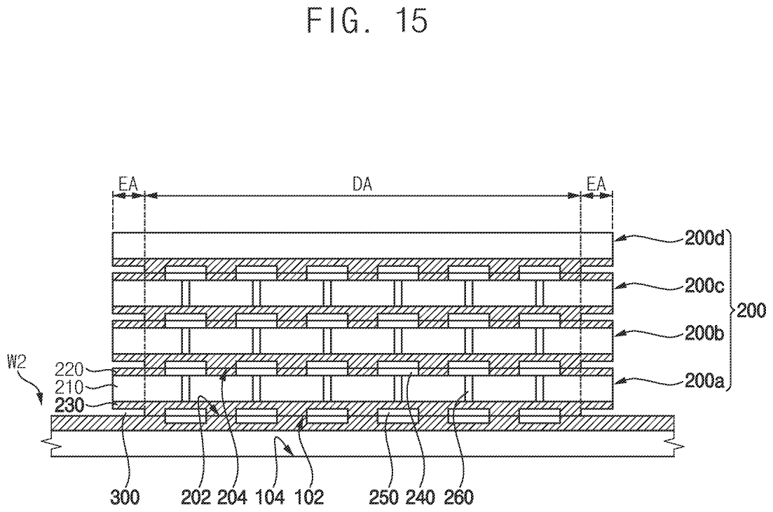

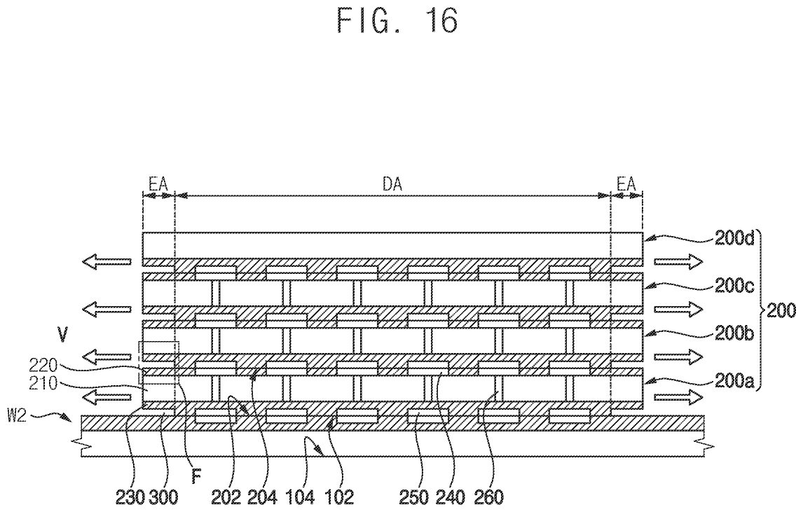

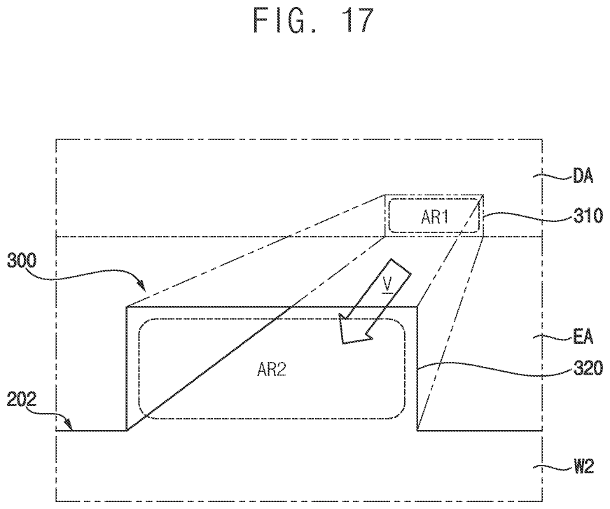

FIGS. 3 to 19 are views illustrating a method of manufacturing a semiconductor package in accordance with example embodiments. FIG. 8 is a cross-sectional view taken along line B-B′ in FIG. 7. FIG. 9 is a plan view illustrating a semiconductor chip formed by cutting a semiconductor wafer. FIG. 10 is a cross-sectional view taken along line C-C′ in FIG. 9. FIG. 11 is an enlarged plan view illustrating a portion ‘D’ in FIG. 9. FIG. 12 is an enlarged plan view illustrating a portion ‘E’ in FIG. 9. FIG. 13 is an enlarged plan view illustrating a portion ‘D’ in FIG. 9 when an additional air exhaust passage is included. FIG. 14 is an enlarged plan view illustrating a portion ‘E’ in FIG. 9 when an additional air exhaust passage is included. FIG. 17 is an enlarged perspective view illustrating a portion ‘F’ in FIG. 16.

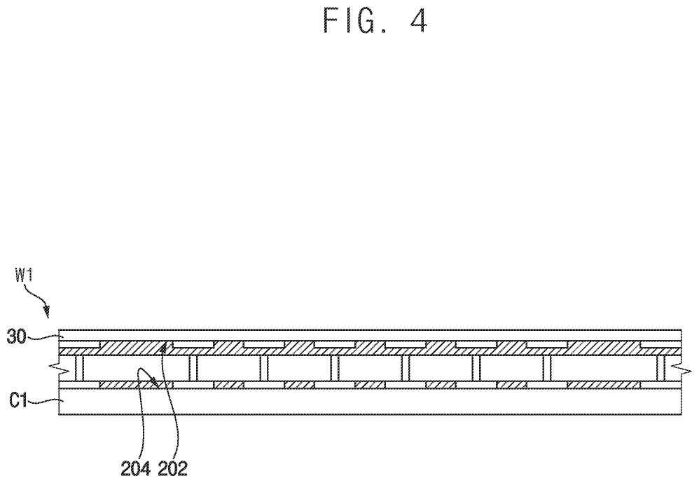

Referring to FIGS. 3 and 4, a semiconductor wafer W1 may be formed on a substrate carrier C1.

In example embodiments, the semiconductor wafer W1 may be a base wafer for forming a plurality of semiconductor chips 200. For example, the semiconductor chips 200 may include a memory chip or a logic chip for forming a semiconductor package 10. The semiconductor package 10 may include a memory device. The memory device may include a high bandwidth memory (HBM) device.

As illustrated in FIG. 3, the semiconductor wafer W1 may be formed on the substrate carrier C1. The semiconductor wafer W1 may include a first surface 202 and a second surface 204 opposite to each other.

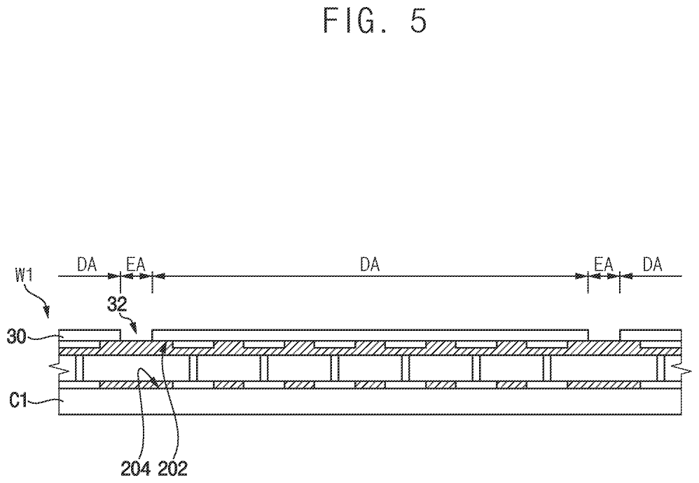

As illustrated in FIGS. 4 and 5, a photoresist layer 30 may be formed on the one surface of the semiconductor wafer W1, and a photoresist pattern 32 may be formed on the photoresist layer 30.

In example embodiments, the photoresist layer 30 may be formed on the semiconductor wafer W1. An exposure process may be performed on the photoresist layer and the photoresist pattern 32 having an opening exposing a region in which an air exhaust passage 300 is to be formed may be formed.

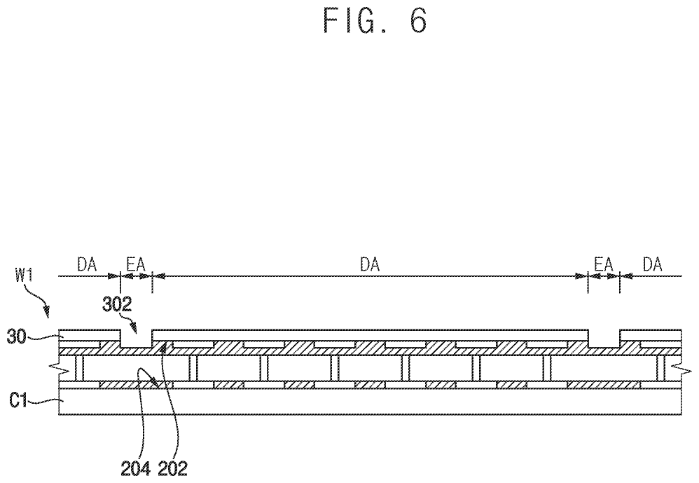

As illustrated in FIGS. 6 to 8, the semiconductor wafer W1 may be etched to form a trench passage 302. After the etching process is completed, the photoresist layer 30 may be removed.

In example embodiments, the trench passage 302 may be formed on the semiconductor wafer W1 through a plasma etching process. The plasma etching process may be a process for etching an etch target layer on the semiconductor wafer W1. The plasma generated in the plasma etching process may include an inductively coupled plasma, a capacitively coupled plasma, a microwave type plasma, or the like. Alternatively, the trench passage 302 may be formed on the semiconductor wafer W through dry etching, wet etching, or the like.

The trench passage 302 may be formed on the photoresist pattern 32 through the plasma etching process. The trench passage 302 may be formed in the edge region EA of the semiconductor wafer W1. The edge region EA may be a region surrounding a die region DA. The edge region EA may be a region in which electrical driving is not performed because a circuit pattern of the semiconductor chip 200 is not formed.

As illustrated in FIG. 7, the trench passage 302 may be formed on a scribe lane region SR in which the semiconductor wafer W1 may be cut. The scribe lane region SR may be a portion cut by a sawing process at the wafer level. The scribe lane region SR may have a rectangular ring shape having a predetermined width from an outer surface of the semiconductor chip 200 between the semiconductor chips 200. The trench passage 302 may be formed to extend between different semiconductor chips 200 in the scribe lane region SR.

As illustrated in FIG. 8, the photoresist layer 30 may be removed from the first surface 202 of the semiconductor wafer W1 after the etching process is completed.

Referring to FIGS. 9 to 14, the semiconductor wafer W1 may be cut to form the semiconductor chip 200.

In example embodiments, the semiconductor wafer W1 may be cut along the scribe lane SR of the semiconductor wafer W1 to form the plurality of semiconductor chips 200. The semiconductor wafer W1 may be cut by a sawing process. The trench passage 302 extending between the semiconductor chips 200 may be cut to form the air exhaust passage 300 in the process of cutting the semiconductor wafer W1.

As illustrated in FIGS. 9 and 10, the die region DA, the edge region EA surrounding the die region DA, and a plurality of the air exhaust passages 300 extending from the die region DA to an outer surface of the edge region EA to exhaust air may be formed on the semiconductor chip 200.

The die region DA may be a region in which the circuit pattern of the semiconductor chip 200 is formed and electrically driven. The die region DA may have a rectangular shape in a plan view. The rectangular shape of the die area DA may include first corner regions ED1 and first vertex regions VE1.

The edge region EA may be a region in which the circuit pattern of the semiconductor chip 200 is not formed. The edge region EA may have the rectangular shape having a predetermined width in the plan view. The edge region EA may have a region overlapping the scribe lane region SR in which the semiconductor wafer W1 is cut in the plan view. The rectangular shape of the edge region EA may include second corner regions ED2 and second vertex regions VE2.

The air exhaust passages 300 may be formed to extend from the die region DA to the outer surface of the edge region EA. The air exhaust passages 300 may be formed in a lower insulating layer 230 of the semiconductor chip 200. For example, the air exhaust passage 300 may have a trench shape in which the lower insulating layer 230 is recessed on the first surface 202 of the semiconductor chip 200.

The air exhaust passage 300 may include an inlet 310 through which the air is introduced and an outlet 320 through which the air is exhausted. The air may be generated in a bonding process for bonding the semiconductor chip 200 with other semiconductor devices.

As illustrated in FIG. 11, the inlet 310 may be formed to be exposed to the first vertex region VE1 of the die region DA. The outlet 320 may be formed to be exposed to the second vertex region VE2 of the edge region EA. In this case, the air exhaust passage 300 may extend from the first vertex region VE1 of the die region DA to the second vertex region VE2 of the edge region EA. The air exhaust passage 300 may exhaust the air generated in the vertex region of the semiconductor chip 200 to an outside of the semiconductor chip 200.

As illustrated in FIG. 12, the inlet 310 may be formed to be exposed to the first edge region ED1 of the die region DA. The outlet 320 may be formed to be exposed to the second edge region ED2 of the edge region EA. In this case, the air exhaust passage 300 may extend from the first edge region ED1 of the die region DA to the second edge region ED2 of the edge region EA, as will be described later, the air exhaust passage 300 may exhaust the air generated in the edge region of the semiconductor chip 200 to the outside of the semiconductor chip 200.

As illustrated in FIGS. 13 and 14, a plurality of second air exhaust passages 400 that respectively branch from the first air exhaust passages 300 may be additionally formed. The trench passage 302 extending between the semiconductor chips 200 may be cut to form second air exhaust passages 400 while the semiconductor wafer W1 is cut.

The second air exhaust passages 400 may extend from the first air exhaust passages 300 to the outer surface of the edge region EA. The second air exhaust passages 400 may be formed in the lower insulating layer 230 of the semiconductor chip 200. For example, the second air exhaust passage 400 may include the trench shape in which the lower insulating layer 230 is recessed on the first surface 202 of the semiconductor chip 200.

The second air exhaust passage 400 may include a second inlet 410 through which the air is introduced and a second outlet 420 through which the air is exhausted. The air may be generated in the bonding process for bonding the semiconductor chip 200 with other semiconductor devices.

The second inlet 410 may be formed on an inner surface of the first air exhaust passage 300. Alternatively, the second inlet 410 may be formed at a boundary between the die region DA and the edge region EA of the semiconductor chip 200.

The second outlet 420 may be formed on the outer surface of the edge region EA of the semiconductor chip 200. The second outlet 420 may be exposed toward the outer surface of the edge region EA.

Referring to FIG. 15, the semiconductor chip 200 may be disposed on a semiconductor substrate W2 such that the air exhaust passage 300 faces the semiconductor substrate W2. The semiconductor chip 200 may be disposed such that the air exhaust passage 300 faces one surface of different semiconductor chips 200.

The plurality of semiconductor chips 200 may be disposed on the semiconductor substrate W2. The first to fourth semiconductor chips 200a, 200b, 200c, 200d may be stacked on the semiconductor substrate W2. The first to fourth semiconductor chips 200a, 200b, 200c, 200d may be respectively fixed on a substrate pad 110 of the semiconductor substrate W2 through a reflow process. The reflow process may be a technical process for stably bonding the first to fourth semiconductor chips 200a, 200b, 200c, 200d to the semiconductor substrate W2 by applying a high temperature heat source.

Referring to FIGS. 16 and 17, voids (i.e., trapped air or gas) between the first to fourth semiconductor chips 200a, 200b, 200c, 200d and the semiconductor substrate W2 may be exhausted to an outside in a process in which the first to fourth semiconductor chips 200a, 200b, 200c, 200d are adhered to the semiconductor substrate W2. The plurality of air exhaust passages 300 may exhaust the voids V generated between the semiconductor chips 200 and the semiconductor substrate W2 to the outside. The voids V may be generated between the semiconductor substrate W2 and the first to fourth semiconductor chips 200a, 200b, 200c, 200d in the reflow process.

As illustrated in FIG. 17, the air exhaust passage 300 may exhaust the voids V (i.e., trapped air or gas) through the inlet 310 having a first passage area AR1 and an outlet 320 having a second passage area AR2. The second passage area of the outlet may be greater than the first passage area of the inlet. Since the second passage area of the outlet is greater than the first passage area of the inlet, a pressure at the outlet may be lower than a pressure at the inlet. The voids may move from the inlet to the outlet due to a pressure difference between the outlet and the inlet.

The inlet 310 may be formed at the boundary between the die region DA and the edge region EA of the semiconductor chip 200. The inlet 310 may introduce the voids V generated between the semiconductor substrate W2 and the semiconductor chip 200 into the air exhaust passage 300. The inlet 310 may have the first passage area AR1.

The outlet 320 may be formed on the outer surface of the edge region EA of the semiconductor chip 200. The outlet 320 may be exposed toward the outer surface of the edge region EA. The outlet 320 may exhaust the voids generated between the semiconductor substrate W2 and the semiconductor chip 200 from the air exhaust passage 300.

The outlet 320 may have the second passage area AR2. The second passage area AR2 of the outlet 320 may be greater than the first passage area AR1 of the inlet 310. Since the second passage area AR2 of the outlet 320 is greater than the first passage area AR1 of the inlet 310, the pressure in the outlet 320 may be lower than the pressure in the inlet 310. The voids may move from the inlet 310 to the outlet 320 by a pressure difference between the outlet 320 and the inlet 310. For example, a ratio AR2/AR1 of the second passage area AR2 of the outlet 320 to the first passage area AR1 of the inlet 310 may be within a range of 1.1 to 3.

When the second air exhaust passages 400 are additionally formed to branch from the air exhaust passages 300, the second inlet 410 may communicate with the first air exhaust passage 300. The second outlet 420 may be formed to be exposed to the second edge region ED2 of the edge region EA. In this case, the second air exhaust passage 400 may extend from the first air exhaust passage 300 to the second edge region ED2 of the edge region EA, and the second air exhaust passage 400 may exhaust the voids generated in the vertex region of the semiconductor chip 200 to the outside of the semiconductor chip 200.

The second inlet 410 may introduce the voids generated between the semiconductor substrate W2 and the semiconductor chip 200 into the second air exhaust passage 400. The second inlet 410 may have a third passage area AR3.

The third passage area AR3 of the second inlet 410 may be greater than the first passage area AR1 of the first inlet 310 of the first air exhaust passage 300. Since the third passage area AR3 of the second inlet 410 is greater than the first passage area AR1 of the first inlet 310 of the first air exhaust passage 300, a pressure in the second inlet 410 may be lower than the pressure in the first inlet 310. The air may move from the first inlet 310 to the second inlet 410 by a pressure difference between the first inlet 310 and the second inlet 410. For example, a ratio AR3/AR1 of the third passage area AR3 of the second inlet 410 to the first passage area AR1 of the first inlet 310 may be within the range of 1.1 to 3.

The second outlet 420 may exhaust the voids generated between the semiconductor substrate W2 and the semiconductor chip 200 from the second air exhaust passage 400.

The second outlet 420 may have a fourth passage area AR4. The fourth passage area AR4 of the second outlet 420 may be greater than the third passage area AR3 of the second inlet 410. Since the fourth passage area AR4 of the second outlet 420 is greater than the third passage area AR3 of the second inlet 410, a pressure in the second outlet 420 may be lower than the pressure in the second inlet 410. The voids may move from the second inlet 410 to the second outlet 420 by a pressure difference between the second outlet 420 and the second inlet 410. For example, a ratio AR4/AR3 of the fourth passage area AR4 of the second outlet 420 to the third passage area AR3 of the second inlet 410 may be within a range of 1.1 to 3.

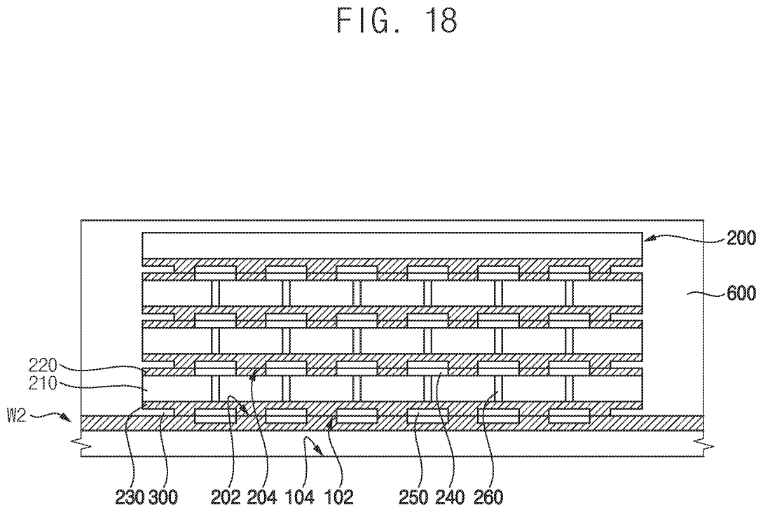

Referring to FIG. 18, a molding member 600 covering the semiconductor chips 200 may be formed on the semiconductor substrate W2. For example, the molding member 600 may include an epoxy mold compound (EMC) or the like.

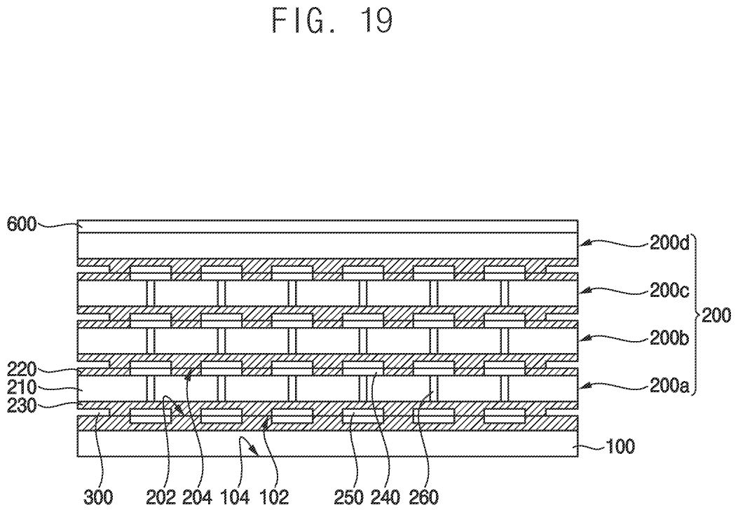

Referring to FIG. 19, the semiconductor package 10 of FIG. 1 may be completed by cutting the semiconductor substrate W2. The semiconductor substrate W2 may be cut through a dicing process.

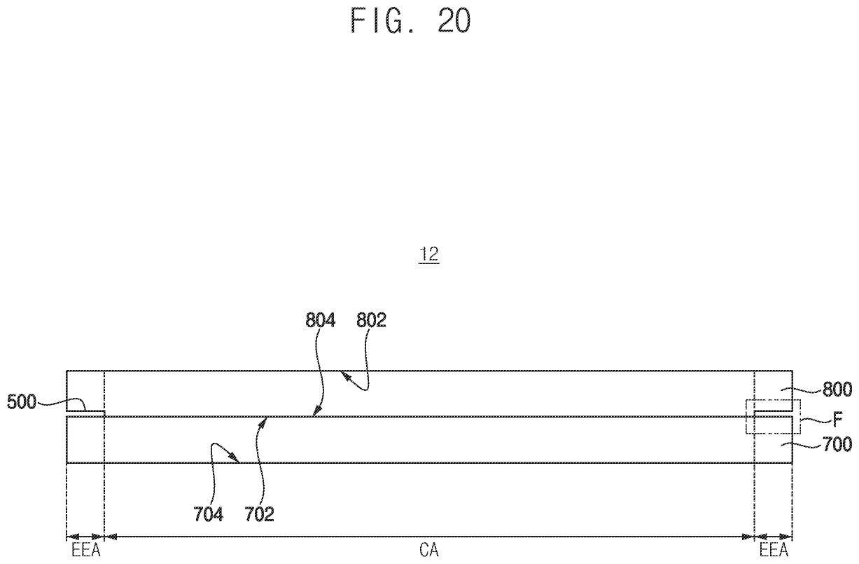

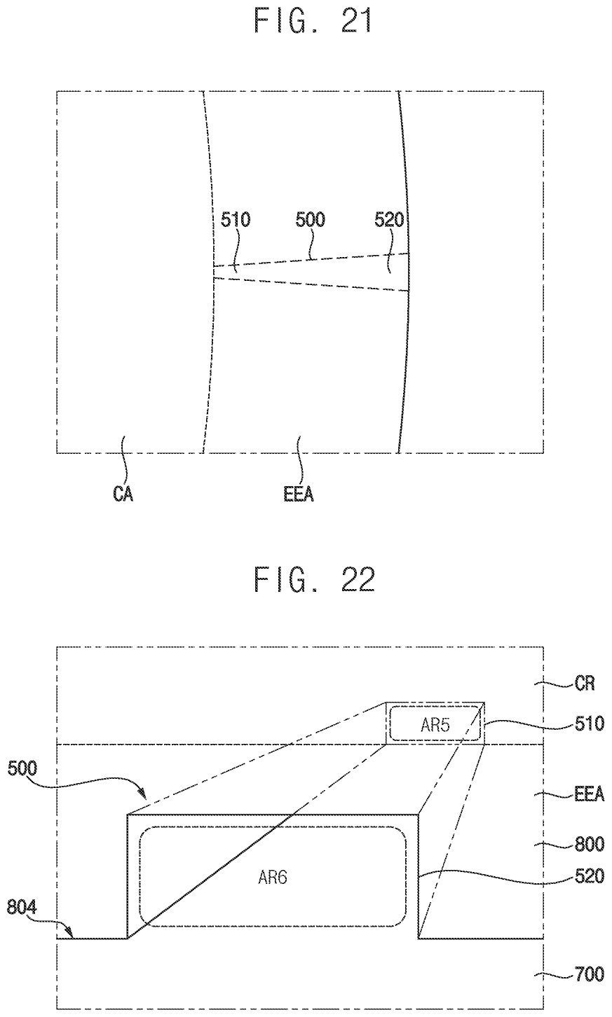

FIG. 20 is a cross-sectional view illustrating a semiconductor package including a plurality of semiconductor substrates in accordance with example embodiments. FIG. 21 is an enlarged plan view illustrating a portion ‘F’ in FIG. 20. FIG. 22 is an enlarged perspective view illustrating a portion ‘F’ in FIG. 20. The semiconductor package may be substantially the same as or similar to the semiconductor package described with reference to FIGS. 1 and 2 except for a configuration of first and second semiconductor substrates. Thus, same or similar components may be denoted by the same or similar reference numerals, and repeated descriptions of the same components will be omitted.

Referring to FIGS. 20 to 22, a semiconductor package 12 may include a first semiconductor substrate 700 and a second semiconductor substrate 800 disposed on the first semiconductor substrate 700. The semiconductor package 12 may further include an adhesive member for attaching the first and second semiconductor substrates 700, 800.

In example embodiments, the first semiconductor substrate 700 may have a first upper surface 702 and a first lower surface 704 opposite to each other. The second semiconductor substrate 800 may have a second upper surface 802 and a second lower surface 804 opposite to each other. The second semiconductor substrate 800 may be disposed on the first semiconductor substrate 700. The first upper surface 702 of the first semiconductor substrate 700 may contact the second lower surface 804 of the second semiconductor substrate 800. For example, the first and second semiconductor substrates 700, 800 may include a semiconductor wafer.

Substrate pads of each of the first and second semiconductor substrates 700, 800 may be bonded to each other by Cu-Cu Hybrid Bonding (pad-to-pad direct bonding) between the first and second semiconductor substrates 700, 800.

In example embodiments, the second semiconductor substrate 800 may include a chip region CR, an outermost edge region EEA surrounding the chip region CR, and a plurality of third air exhaust passages 500 extending from the chip region CR to an outer surface of the outermost edge region EEA to exhaust trapped air or gas.

The chip region CR may have a circular shape in the plan view. The outermost edge region EEA may have a circular annular shape having a predetermined width in the plan view.

In example embodiments, the third air exhaust passages 500 may exhaust the voids (i.e., trapped air or gas) generated between the first and second semiconductor substrates 700, 800 to an outside of the semiconductor package 12. The third air exhaust passages 500 may be provided on the second lower surface 804 of the second semiconductor substrate 800 contacting the first semiconductor substrate 700.

The third air exhaust passages 500 may be formed by performing the same or similar processes as those described with reference to FIGS. 3 to 8. A photoresist layer may be formed on the second lower surface 804 of the second semiconductor substrate 800, and an exposure process may be performed on the photoresist layer to form a photoresist pattern. Subsequently, the second lower surface 804 of the second semiconductor substrate 800 may be etched to form third air exhaust passages 500. After the etching process is completed, the photoresist layer may be removed.

The third air exhaust passages 500 may extend from the chip region CR to the outer surface of the outermost edge region EEA. For example, the third air exhaust passage 500 may include the trench shape recessed from the second lower surface 804 of the second semiconductor substrate 800.

The third air exhaust passage 500 may include a third inlet 510 through which the voids are introduced and a third outlet 520 through which the voids are exhausted. The voids may be generated in a bonding process of bonding the first and second semiconductor substrates 700, 800. The voids may be generated between the first and second semiconductor substrates 700, 800.

The third inlet 510 may be provided at a boundary between the chip region CR and the outermost edge region EEA of the second semiconductor substrate 800. The third inlet 510 may introduce the voids generated between the first and second semiconductor substrates 700, 800 into the third air exhaust passage 500. The third inlet 510 may have a fifth passage area AR5.

The third outlet 520 may be provided on the outer surface of the outermost edge region EEA of the second semiconductor substrate 800. The third outlet 520 may be exposed toward the outer surface of the outermost edge region EEA. The third outlet 520 may exhaust the voids generated between the first and second semiconductor substrates 700, 800 from the third air exhaust passage 500.

The third outlet 520 may have a sixth passage area AR6. The sixth passage area AR6 of the third outlet 520 may be greater than the fifth passage area AR5 of the third inlet 510. Since the sixth passage area AR6 of the third outlet 520 is greater than the fifth passage area AR5 of the third inlet 510, a pressure in the third outlet 520 may be lower than a pressure in the third inlet 510. Trapped air or gas may move from the third inlet 510 to the third outlet 520 by a pressure difference between the third outlet 520 and the third inlet 510. For example, a ratio AR6/AR5 of the sixth passage area AR6 of the third outlet 520 to the fifth passage area AR5 of the third inlet 510 may be within a range of 1.1 to 3.

The foregoing is illustrative of example embodiments and is not to be construed as limiting thereof Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package, comprising:
a semiconductor substrate; and
at least one semiconductor chip in contact with the semiconductor substrate, the at least one semiconductor chip comprising a first surface facing the semiconductor substrate, an opposite second surface, a die region, an edge region extending around the die region, and a plurality of air exhaust passages extending from the die region to an outer surface of the edge region in the first surface,
wherein each of the air exhaust passages comprises:
an inlet having a first passage area; and
an outlet having a second passage area greater than the first passage area.

2. The semiconductor package of claim 1, wherein the air exhaust passages are provided in a scribe lane region of the at least one semiconductor chip inside the edge region.

3. The semiconductor package of claim 1, wherein each of the die region and the edge region has a rectangular shape in plan view,
each of the air exhaust passages extends from first corner regions of the die region to second corner regions of the edge region.

4. The semiconductor package of claim 1, wherein each of the die region and the edge region has a rectangular shape in plan view,
each of the air exhaust passages extends from first vertex regions of the die region to second vertex regions of the edge region.

5. The semiconductor package of claim 1, wherein the at least one semiconductor chip further comprises a plurality of second air exhaust passages that respectively branch from the air exhaust passages and extend to the outer surface of the edge region.

6. The semiconductor package of claim 5, wherein each of the second air exhaust passages comprises:
a second inlet having a third passage area; and
a second outlet having a fourth passage area greater than the third passage area.

7. The semiconductor package of claim 1, wherein each of the air exhaust passages comprises a trench shape recessed in the first surface.

8. The semiconductor package of claim 1, wherein the semiconductor substrate further comprises a chip region, an outermost edge region extending around the chip region, and a plurality of third air exhaust passages extending from the chip region to a second outer surface of the outermost edge region, and
wherein the third air exhaust passage comprises:
a third inlet having a fifth passage area; and
a third outlet having a sixth passage area greater than the fifth passage area.

9. The semiconductor package of claim 1, wherein a ratio of the second passage area to the first passage area is within a range of 1.1 to 3.

10. The semiconductor package of claim 1, wherein the semiconductor substrate comprises a semiconductor wafer.

11. A semiconductor package, comprising:
a semiconductor substrate; and
at least one semiconductor chip on the semiconductor substrate, the at least one semiconductor chip comprising a first surface in contact with the semiconductor substrate, an opposite second surface, a die region, an edge region extending around the die region, and a plurality of air exhaust passages extending from the die region to an outer surface of the edge region, each air exhaust passage comprising an inlet having a first passage area and an outlet having a second passage area greater than the first passage area.

12. The semiconductor package of claim 11, wherein the air exhaust passages are provided in a scribe lane region of the at least one semiconductor chip inside the edge region.

13. The semiconductor package of claim 11, wherein each of the die region and the edge region has a rectangular shape in plan view,
wherein each of the air exhaust passages extends from first corner regions of the die region to second corner regions of the edge region.

14. The semiconductor package of claim 11, wherein each of the die region and the edge region has a rectangular shape in plan view,
wherein each of the air exhaust passages extends from first vertex regions of the die region to second vertex regions of the edge region.

17. The semiconductor package of claim 11, wherein the at least one semiconductor chip further comprises a plurality of second air exhaust passages that branch from the air exhaust passages and extend to the outer surface of the edge region.

16. The semiconductor package of claim 15, wherein each of the second air exhaust passages comprises:
a second inlet having a third passage area; and
a second outlet having a fourth passage area greater than the third passage area.

17. The semiconductor package of claim 11, wherein each air exhaust passage comprises a trench shape recessed in the first surface.

18. The semiconductor package of claim 11, wherein the semiconductor substrate further comprises a chip region, an outermost edge region extending around the chip region, and a plurality of third air exhaust passages extending from the chip region to a second outer surface of the outermost edge region, and
wherein the third air exhaust passage comprises:
a third inlet having a fifth passage area; and
a third outlet having a sixth passage area greater than the fifth passage area.

19. The semiconductor package of claim 11, wherein a ratio of the second passage area to the first passage area is within a range of 1.1 to 3.

20. A semiconductor package, comprising:
a first semiconductor substrate; and
a second semiconductor substrate on the first semiconductor substrate, the second semiconductor substrate comprising a chip region, an outermost edge region extending around the chip region, and a plurality of air exhaust passages recessed from a first surface that faces the first semiconductor substrate and extending from the chip region to an outer surface of the outermost edge region,
wherein each of the air exhaust passages comprises:
an inlet having a first passage area; and
an outlet having a second passage area greater than the first passage area.
